(19) United States
(12) Patent Application Publication
(10) Pub. No.: US 2007/0145591 A1
(43) Pub. Date: Jun. 28, 2007

(54) Semiconductor device and manufacturing method therof

(76) Inventors: Hisashi Yano, Kyoto (JP); Masakazu Hamada, Osaka (JP); Kazuyoshi Maekawa, Tokyo (JP); Kenichi Mori, Tokyo (JP)

Correspondence Address: MCDERMOTT WILL & EMERY LLP, 600 13TH STREET, NW, WASHINGTON, DC, 20005-3096, US

(21) Appl. No.: 11/646,432

(22) Filed: Dec. 28, 2006

(30) Foreign Application Priority Data
Dec. 28, 2005 (JP) 2005-379311

(51) Int. Cl. H01L 23/52

(52) U.S. Cl. 257/758

(57) ABSTRACT

The semiconductor device manufacturing method includes the steps of: applying a first wire including a barrier metal film, a seed film, and a wiring material film in a first wire trench formed in a first interlayer dielectric film; after a second interlayer dielectric film is formed on the first interlayer dielectric film, forming a via hole and a second wire trench in the second interlayer dielectric film so as to expose the wiring material film; applying a barrier metal film on the semiconductor device; and after the barrier metal film on the wiring material film is removed by using, for example, a re-sputtering process, applying a barrier metal film on the wiring material film. The re-sputtering process can remove an oxide film of impurity metal in the seed film applied on the wiring material film.

### BACKGROUND OF THE INVENTION

1. Field of the Invention

The present invention relates to a semiconductor device having a structure of a metal wire provided in a trench and to a manufacturing method of the semiconductor device.

2. Description of the Related Art

In recent years, due to progressing reduction of a wiring pitch in a device, it becomes increasingly important to ensure reliability of wiring. For this purpose, investigations have been made to improve the reliability by adding a variety of elements to copper used as a wiring material.

A conventional semiconductor device having an embedded wire will be explained below. FIGS. 6A through 6I are cross sections illustrating a conventional manufacturing method of the semiconductor device.

First, referring to FIG. 6A, a lithography step and an etching step are carried out to form a first wire trench 102 in a first interlayer dielectric film 101, the first interlayer dielectric film 101 being formed of a low dielectric constant material on a substrate (not shown). Next, as a preparatory process, an annealing step is performed on the substrate (semiconductor device) for 60 seconds in a hydrogen atmosphere at a temperature of 280° C. so as to reduce an oxide formed on a surface of the semiconductor device. Then, as a barrier metal film 103, a tantalum nitride film having a thickness of 5 nm and a tantalum film having a thickness of 10 nm are sequentially formed on the first interlayer dielectric film 101. In this case, the barrier metal film 103 is a metal film preventing the copper, which is a wiring material, from diffusing into the first interlayer dielectric film 101 provided around the wiring material.

Subsequently, referring to FIG. 6B, a seed film 104 having a thickness of 40 nm is formed on the barrier metal film 103. In this case, copper containing 1% Al is used as a material for the seed film 104. A purpose of adding metal to copper is to improve, for example, electromigration resistance and stress migration resistance, and thus to improve the reliability of the semiconductor device.

Next, a copper film 105 is formed on the seed film 104 by using a plating method to fill the first wire trench 102. Then, the copper film 105, the seed film 104, and the barrier metal film 103 are polished by chemical mechanical polishing (CMP) such that the barrier metal film 103, the seed film 104, and the copper film 105 remain only in the first wire trench 102 as shown in FIG. 6C. In this way, a first wire is formed.

Next, referring to FIG. 6D, a liner film 106 having a thickness of about 60 nm is formed on the first wire and the first interlayer dielectric film 101. In this case, the liner film 106 prevents the copper included in the wire from diffusing into a second interlayer dielectric film which is to be formed in a later step. The liner film 106 is formed of a silicon nitride film, silicon-carbon film, or other materials having the relative dielectric constant higher than that of a material for the interlayer dielectric film.

Next, referring to FIG. 6E, a second interlayer dielectric film 107 of a low dielectric constant material is formed on the liner film 106.

Subsequently, referring to FIG. 6F, lithography and etching steps are performed repeatedly in order to form a via hole 108 which reaches the copper film 105 and a second wire trench 109 to which the via hole 108 is open in the second interlayer dielectric film 107.

Next, referring to FIG. 6G, as a preparatory process, an annealing process is performed on the semiconductor device for 60 seconds in a hydrogen atmosphere at a temperature of 280° C. so as to remove an oxide formed on a surface of the semiconductor device. Then, as a barrier metal film 110, a tantalum nitride film having a thickness of 5 nm and a tantalum film having a thickness of 10 nm are sequentially formed on inner surfaces of the via hole 108 and the second wire trench 109 and on the second interlayer dielectric film 107.

Subsequently, referring to FIG. 6H, a seed film 111 having a thickness of about 40 nm is formed on the barrier metal film 110. In this case, as a material for the seed film 111, copper containing 1% Al is used similar to the seed film 104. A purpose of adding metal to copper is to improve resistance against, for example, electromigration and stress migration, and thus to improve the reliability of the semiconductor device.

Next, referring to FIG. 6I, a copper film 112 is formed on the seed film 111 by using a plating method to fill the second wire trench 109 and the via hole 108. Then, the barrier metal film 110, the seed film 111, and the copper film 112 are polished by CMP such that the barrier metal film 110, the seed film 111, and the copper film 112 remain only in the second wire trench 109 and the via hole 108. In this way, a plug and a second wire are formed.

### SUMMARY OF THE INVENTION

However, the structure of the above-mentioned conventional semiconductor device and the manufacturing method have a problem that the resistance value between a plug and a wire may increase. In such a case, the yield of the semiconductor device decreases.

FIG. 7 shows the cumulative frequency distribution of via resistance values in a case where wires embedded in multiple layers are formed according to the conventional method.

It should be designed that all of the via resistance values are 2×10⁷ Ω or lower. However, the FIG. 7 shows that the via resistance values are broadly distributed and the via resistance increases. The inventors of the present invention carried out various investigations as to the cause of the increased via resistance and as a result found that the increased via resistance is attributable to an Al oxide which is formed on a copper wire but not sufficiently removed.

FIG. 8 shows a mechanism which is considered to be a cause of the increased resistance between the wire and the plug in the conventional method. In the conventional manufacturing method, heating after the formation of the first wire distributes Al included in the seed film 104 in the copper film 105, which forms a CuAl alloy. Especially, it is considered that after the via hole 108 is formed, the Al included in the seed film 104 bonds with atmospheric oxygen, so that not only a Cu oxide but also an Al oxide are formed on upper surface of the copper film 105 and on upper end surfaces of the seed film 104. The Al oxide can not be reduced in an annealing process in the hydrogen atmosphere performed before the formation of the barrier metal film 110, because the Al oxide has the intermolecular bond energy significantly stronger than that of the Cu oxide. For this reason, it can be considered that an Al oxide film 113 formed on the first wire can not be removed, so that the resistance value between the wire and the plug increases.

An object of the invention is to provide a semiconductor device without the above-mentioned problems, the semiconductor device being manufactured with a good yield and having high reliability and another object of the invention is to provide a manufacturing method of such semiconductor device.

In order to solve the above-mentioned problems, investigations have been carried out, and it turned out that a metal added to a seed film forms an oxide on the upper surface of a wiring material (copper film) but the oxide is not sufficiently removed. To cope with this problem, the invention includes the step of removing the metal oxide film.

That is, the semiconductor device according to the present invention includes: a first interlayer dielectric film on a substrate; a first wire in the first interlayer dielectric film, the first wire including a first wiring material film which contains at least one element of metal; a second interlayer dielectric film on the first interlayer dielectric film and the first wire, the second interlayer dielectric film having a trench in which the first wiring material film is exposed; an oxide film of the metal between upper end surfaces of the first wiring material film and the second interlayer dielectric film; and a second wire including a barrier metal film and a second wiring material film in the trench.

An increase in the electric resistance between the plug and the wire provided in the via hole can be suppressed, as long as the metal oxide film is not formed in a region on the first wiring material film over which the second interlayer dielectric film does not extend. Note that, the metal oxide films remaining on the upper end surfaces of the seed film can not be a problem, because the upper end surfaces of the seed film are not current paths.

A first semiconductor device manufacturing method according to the present invention includes the steps of: (a) forming a first wiring material film in a first interlayer dielectric film formed on a substrate; (b) forming a second interlayer dielectric film on the first wiring material film and the first interlayer dielectric film; (c) forming a trench in the second interlayer dielectric film to expose the first wiring material film; (d) forming a barrier metal film in the trench; (e) forming a concavity in an upper part of the first wiring material film by removing a part of the barrier metal film over the first wiring material film and a part of the first wiring material; and (f) forming a second wiring material film to fill the trench and the concavity, wherein the first wiring material film contains at least one element of metal; an oxide film of the metal is formed on an upper surface of the first wiring material film in steps (a) and (c); and step (e) includes removing an exposed part of the oxide film of the metal formed on the upper surface of the first wiring material film.

According to this method, the metal oxide film formed on the first wiring material film is removed, so that it is possible to reduce the resistance value between the plug and the wire more than the conventional method reduces it.

A second semiconductor device manufacturing method according to the present invention includes the steps of: (a) forming a first wiring material film in a first interlayer dielectric film formed on a substrate; (b) forming a second interlayer dielectric film on the first wiring material film and the first interlayer dielectric film; (c) forming a trench in the second interlayer dielectric film to expose the first wiring material film; (d) performing a hydrogen plasma process on the first wiring material film; (e) after step (d), forming a barrier metal film in the trench; and (f) after step (e), forming a second wiring material film to fill the trench, wherein the first wiring material film contains at least one element of metal, an oxide film of the metal is formed on an upper surface of the first wiring material film in steps (a) and (c), and step (d) includes removing an exposed part of the oxide film of the metal formed on the upper surface of the first wiring material film.

In the method described above, the oxide film of the metal is first removed from the first wiring material film, and then the barrier metal film is formed. This makes it possible to reduce the resistance value between the plug and the wire more than the conventional method reduces it.

### BRIEF DESCRIPTION OF THE DRAWINGS

FIGS. 1A through 1F are cross sections illustrating a semiconductor device manufacturing method according to Embodiment 1 of the present invention.

FIGS. 2A through 2E are cross sections illustrating the semiconductor device manufacturing method according to Embodiment 1 of the present invention.

FIG. 3 is a cross section illustrating a semiconductor device manufactured according to Embodiment 1, with which the characteristics of the semiconductor device manufacturing method of Embodiment 1 are described.

FIGS. 4A through 4I are cross sections illustrating a semiconductor device manufacturing method according to Embodiment 2 of the present invention.

FIG. 5 is a cross section illustrating a semiconductor device manufactured according to Embodiment 2, with which the characteristics of the semiconductor device manufacturing method of Embodiment 2 are described.

FIGS. 6A through 6I are cross sections illustrating a conventional semiconductor device manufacturing method.

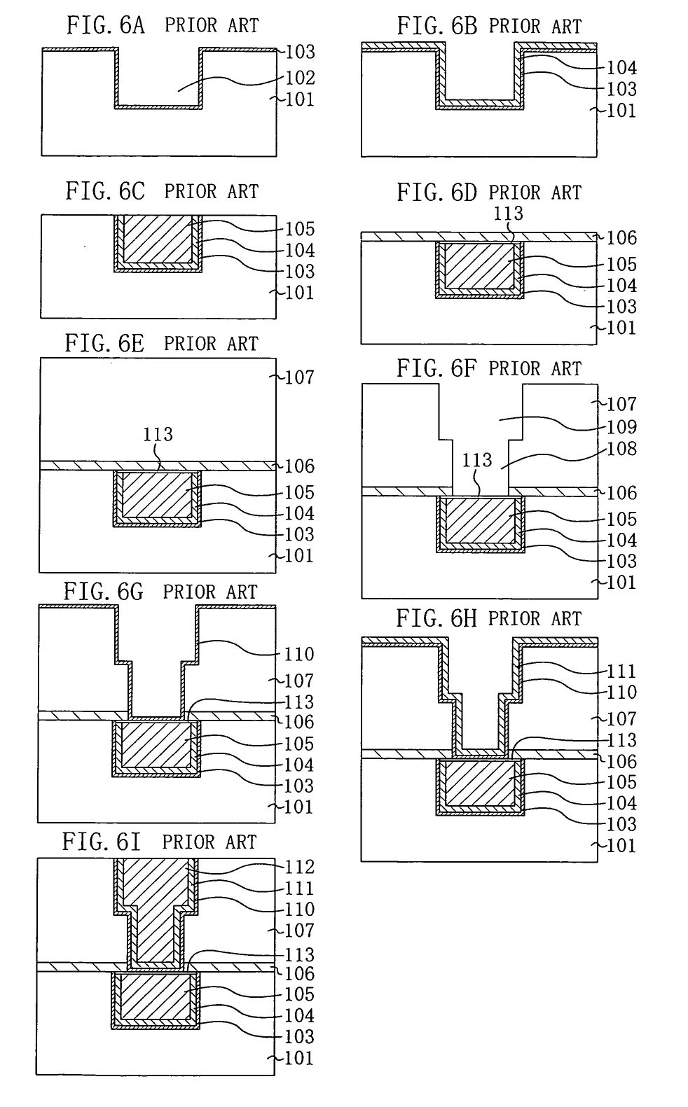

FIG. 7 is a diagram illustrating the cumulative frequency distribution of via resistance values in a case where wires embedded in multiple layers are formed according to the conventional method.

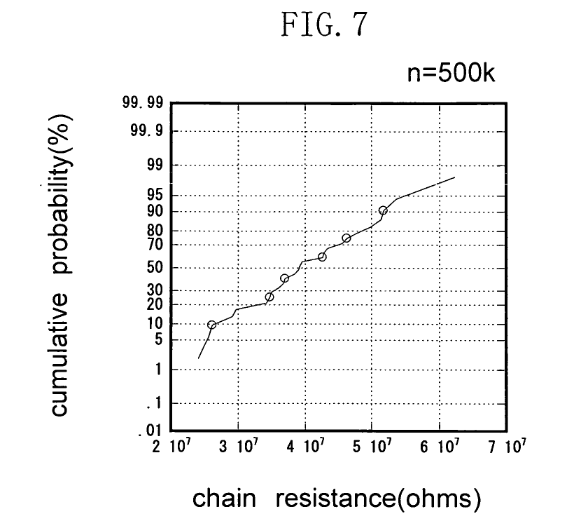

FIG. 8 illustrates a mechanism which is considered to be a cause of the increased via resistance in the conventional method.

### DESCRIPTION OF THE PREFERRED EMBODIMENTS

### Embodiment 1

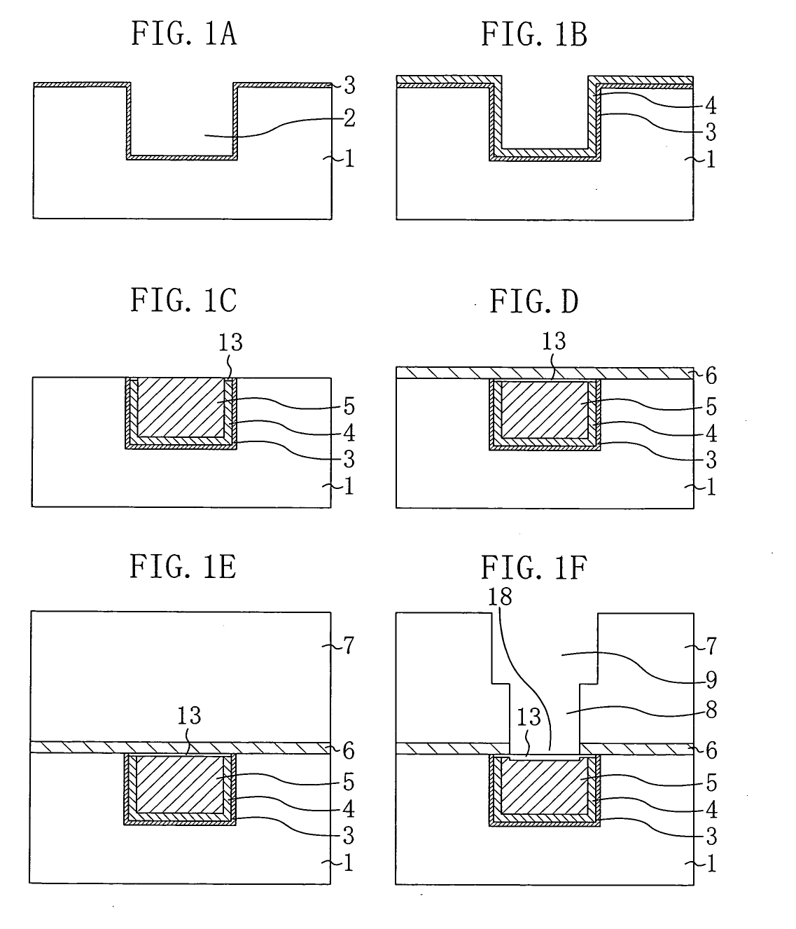

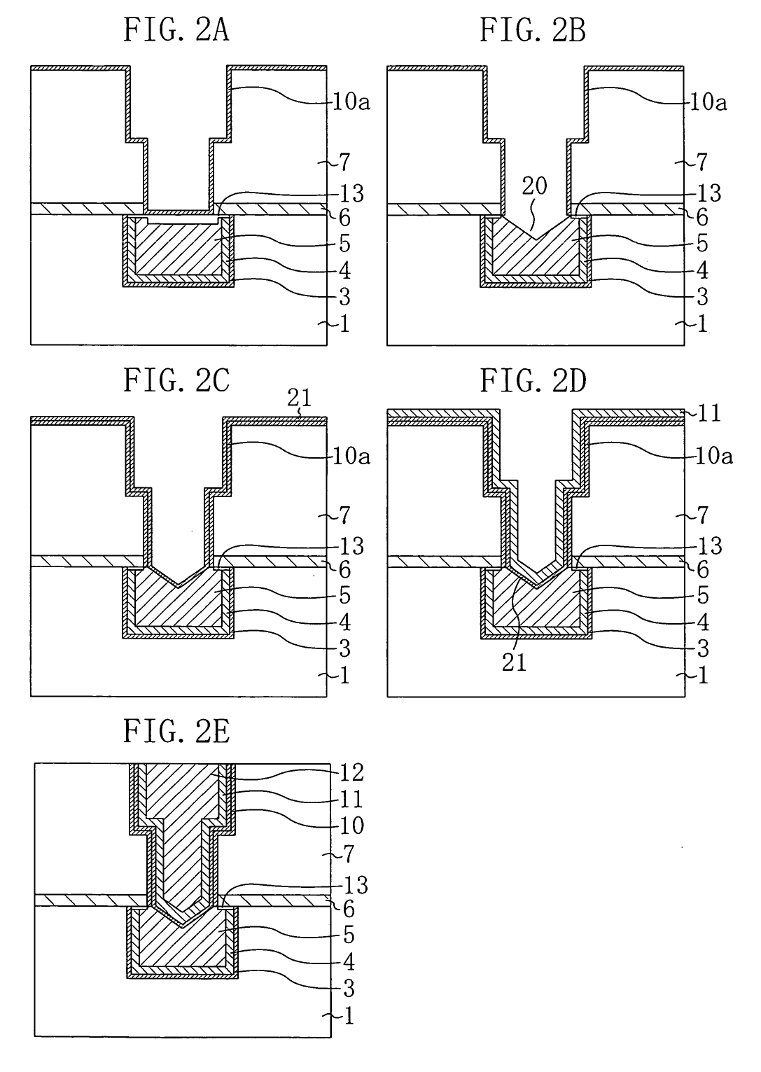

FIGS. 1A through 1F and FIGS. 2A through 2E are cross sections illustrating a semiconductor device manufacturing method according to Embodiment 1 of the present invention.

First, referring to FIG. 1A, a lithography step is performed to form a resist. Then, an etching process is performed using the resist as a mask so as to form a first wire trench 2 in a first interlayer dielectric film 1, the first interlayer dielectric film 1 being formed of a low dielectric constant material on a substrate (not shown). Next, as a preparatory process, an annealing process is performed on the substrate (semiconductor device) for 60 seconds in a hydrogen atmosphere at a temperature of 280° C. so as to reduce an oxide formed on a surface of the semiconductor device. Then, as a barrier metal film 3, a tantalum nitride film having a thickness of 5 nm and a tantalum film having a thickness of 10 nm are formed by, for example, sputtering. In this case, the barrier metal film 3 is a metal film preventing the copper, which is a wiring material, from diffusing into the first interlayer dielectric film 1 provided around the wiring material.

Subsequently, referring to FIG. 1B, a seed film 4 having a thickness of 40 nm is formed on the barrier metal film 3 by, for example, sputtering. In this case, copper containing 1% Al is used as a material for the seed film 4. A purpose of adding metal to copper is to improve, for example, electromigration resistance and stress migration resistance, and thus to improve the reliability of the semiconductor device.

Next, a copper film 5 is formed on the seed film 4 by using a plating method to fill the first wire trench 2. Then, the copper film 5, the seed film 4, and the barrier metal film 3 are polished by CMP such that the barrier metal film 3, the seed film 4, and the copper film 5 remain only in the first wire trench 2 as shown in FIG. IC. In this way, a first wire is formed. In the step of forming the first wire, Al included in the seed film 4 diffuses into the copper film 5. Moreover, Al included in the seed film 4 reacts with atmospheric oxygen, which results in an Al oxide film 13 including a thin Al₂O₃ film formed on upper end surfaces of the seed film 4.

Next, referring to FIG. 1D, a liner film 6 having a thickness of about 60 nm is formed on the first wire and on the first interlayer dielectric film 1 by, for example, CVD. In this case, the liner film 6 prevents the copper included in the first wire from diffusing into a second interlayer dielectric film which is to be formed in a later step. The liner film 6 is formed by a silicon-carbon film or silicon nitride film having the relative dielectric constant higher than that of a material for the interlayer dielectric film. Note that, heating during the formation of the liner film 6 causes Al included in the seed film 4 to diffuse into the vicinity of an upper surface of the copper film 5. Therefore, a thin Al oxide film 13 is also formed on the upper surface of the copper film 5.

Next, referring to FIG. 1E, a second interlayer dielectric film 7 of a low dielectric constant material is formed on the liner film 6 by, for example, CVD. Heating during the formation of the second interlayer dielectric film 7 also causes Al to diffuse into the copper film 5.

Subsequently, referring to FIG. 1F, lithography and etching steps are performed repeatedly in order to form a via hole 8 reaching the copper film 5 and a second wire trench 9 to which the via hole 8 is open in the second interlayer dielectric film 7. Moreover, an opening 18 is formed in the liner film 6. In this step, the upper surface of the copper film 5 is exposed, so that the thickness of the Al oxide film 13 formed on the upper surface of the copper film 5 increases. In this step, more Al oxide is formed than in other steps.

Next, referring to FIG. 2A, as a preparatory process, an annealing process is performed on the semiconductor device for 60 seconds in a hydrogen atmosphere at a temperature of 280° C. so as to reduce an oxide formed on a surface of the semiconductor device. However, the annealing process can not sufficiently reduce the Al oxide film 13, because the Al oxide has the intermolecular bond energy significantly stronger than that of the Cu oxide. Then, as a barrier metal film 10a, a tantalum nitride film having a thickness of 5 nm and a tantalum film having a thickness of 10 nm are sequentially formed.

Subsequently, referring to FIG. 2B, in the same reaction chamber used to form the barrier metal film 10a, a re-sputtering process using Ar is performed so as to remove the barrier metal film 10a on the copper film 5, and the Al oxide film 13 in connection with the barrier metal film 10a (the Al oxide film 13 directly beneath the via hole 8). At this time, the copper film is also removed partially, forming a concavity 20 having a downward convex form.

Next, referring to FIG. 2C, a tantalum film having a thickness of 5 nm as a barrier metal film 21 is formed on an exposed part of the copper film 5 (i.e., on an inner surface of the concavity 20) and on the barrier metal film 10a by, for example, sputtering.

Subsequently, referring to FIG. 2D, a seed film 11 having a thickness of 40 nm is formed on the barrier metal films 10a and 21 by, for example, sputtering. In this case, as a material for the seed film 11, similar to the seed film 4, copper containing 1% Al is used. A purpose of adding metal to copper is to improve, for example, electromigration resistance and stress migration resistance, and thus to improve the reliability of the semiconductor device.

Next, referring to FIG. 2E, a copper film 12 is formed on the seed film 11 by using a plating method such that the copper film 12 fills the second wire trench 9, the via hole 8, the opening 18, and the concavity 20. Then, CMP is performed to polish the barrier metal film 10a, the seed film 11, and the copper film 12 in order to expose an upper surface of the second interlayer dielectric film 7. As a result, a plug and a second line including the barrier metal film 10, the seed film 11, and the copper film 12 are formed, wherein the barrier metal film 10, the seed film 11, and the copper film 12 are provided on inner surfaces of the second wire trench 9, the opening 18, the via hole 8 and the concavity 20. Here, the barrier metal film 10 illustrated in FIG. 2E refers to both the barrier metal film 10a on the inner surface of the second wire trench 9 and the via hole 8 and the barrier metal film 21. In this way, an embedded wire according to Embodiment 1 is formed.

As shown in FIG. 2E, the semiconductor device manufactured according to the method of Embodiment 1 includes: the first interlayer dielectric film 1 on the substrate formed of, for example, silicon, the first interlayer dielectric film 1 including the low dielectric constant material which has the first wire trench 2; the barrier metal film 3 on an inner surface of the first wire trench 2, the barrier metal film 3 being formed of, for example, the tantalum nitride film and the tantalum film; the seed film 4 on the barrier metal film 3, the seed film 4 being formed of copper (wiring metal) containing, for example, 1% Al by weight; the copper film (first wiring material film) 5 on the seed film 4, the copper film 5 being provided in the first wire trench 2, and the upper surface of the copper film 5 having the concavity 20; the liner film 6 on the first interlayer dielectric film 1, the liner film 6 being formed of a dielectric film which has the opening 18 formed in a region directly over the concavity 20; and the Al oxide film 13 formed between the upper end surfaces of the seed film 4 and copper film 5 and the liner film 6. The semiconductor device according to Embodiment 1 further includes: the second interlayer dielectric film 7 including the low dielectric constant material in which the via hole 8 and the second wire trench 9 are formed, one end of the via hole 8 being open to the opening 18 of the liner film 6 and the other end of the via hole 8 being open to the second wire trench 9; the barrier metal film 10 on the inner surfaces of the second wire trench 9, the via hole 8, the opening 18 and the concavity 20, the barrier metal film 10 being formed of, for example, the tantalum nitride film and the tantalum film; the seed film 11 on the barrier metal film 10, the seed film 11 including copper which contains, for example, 1% Al by weight; and the copper film (second wiring material film) 12 on the seed film 11, the copper film 12 being provided in the second wire trench 9, the via hole 8, the opening 18 and the concavity 20. The width of the second wire trench is, for example, 0.1 μm and the depth is, for example, 0.15 μm.

As described above, in the conventional wire formation method, the resistance between the wire and the plug increases, because the Al oxide formed on the copper wire is not removed sufficiently.

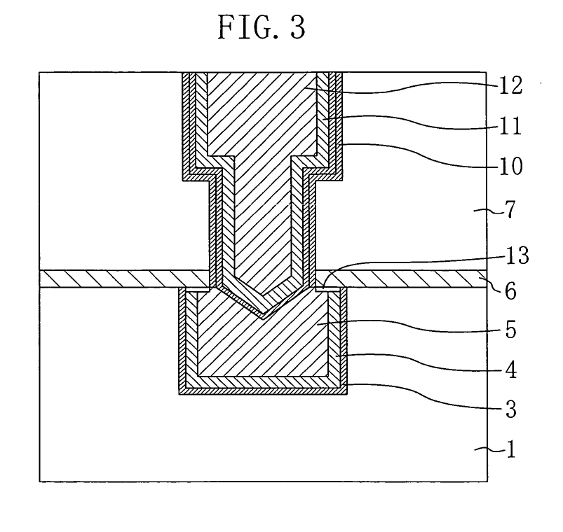

Compared to the conventional method, in the manufacturing method of Embodiment 1, a re-sputtering process is performed in the step illustrated with FIG. 2B after the barrier metal film 10a is formed. The re-sputtering process removes a part of the barrier metal film 10a and the Al oxide formed on the copper film 5. In this way, the Al oxide which is dielectric and formed on a current transferring path between the wire and the plug is removed. This makes it possible to reduce the resistance between the wire and the plug. Note that, as shown in FIG. 3, the Al oxide film remains between the upper end surfaces of the copper film 5 and seed film 4 and the liner film 6. However, this can not be a problem, because a current transferring path is not formed between the upper end surfaces of the copper film 5 and seed film 4 and the liner film 6. In sum, the method according to Embodiment 1 can suppress the increase in the resistance value between the wire and the plug, and at the same time, it is possible to manufacture semiconductor device with a good yield and suppressed occurrences of electromigration and stress migration.

The semiconductor device according to Embodiment 1 has been described with reference to the example of using copper in which 1% Al is added as materials for the seed films 4 and 11. However, removing the Al oxide achieves the lowered electric resistance between the wire and the plug regardless of the amount of Al added. Metal to be added to materials forming the seed films 4 and 11 is not limited to Al. Any metal having binding energy with oxygen higher than copper may be used. For example, Mg, Zn, Fe, Sn, or Ti may be added to materials forming the seed films 4 and 11. More than one element of metal which has the binding energy with oxygen higher than that of the copper may be added to the seed film material (e.g., copper).

The manufacturing method in Embodiment 1 is effective also in a case where the seed film 11 of the second wire consists of copper.

In the description above, an example where two embedded wires are formed has been explained. However, repeating the similar wire formation step can form wires in multiple layers.

In the semiconductor device in Embodiment 1, as a material for an interlayer dielectric film, a low dielectric constant material including, for example, SiOC is used. However, the method according to Embodiment 1 can be applied to a case where a general silicon oxide is used.

It is most preferable that the copper is used as a wiring material. However, any low-resistance metal other than copper may be used.

### Embodiment 2

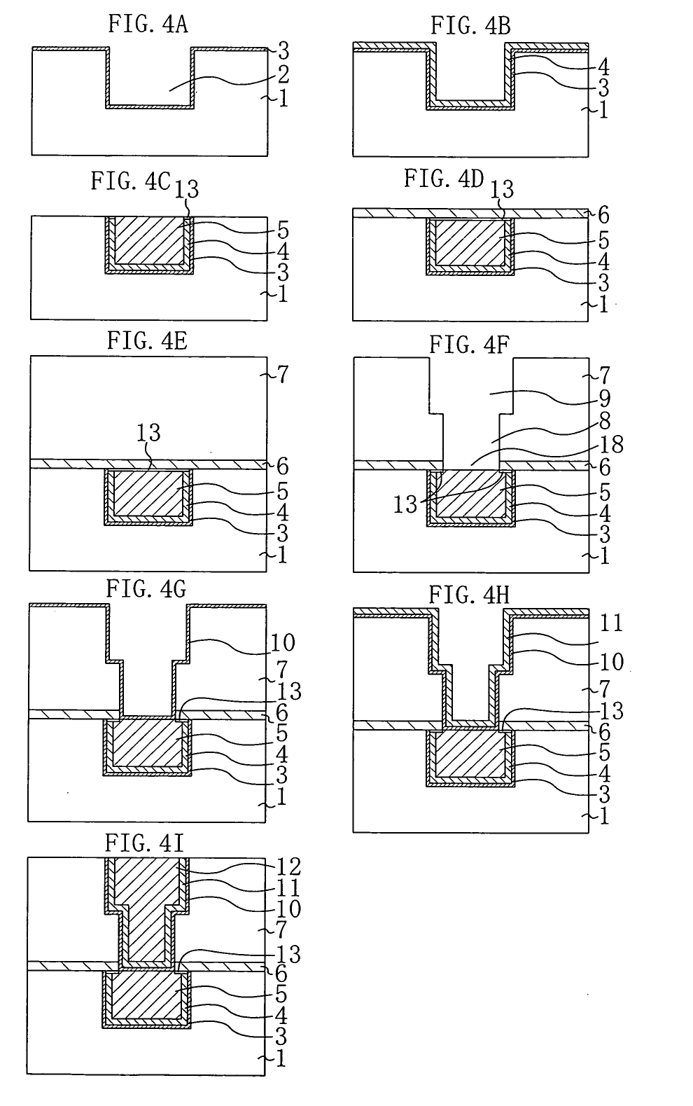

FIGS. 4A through 4I are cross sections illustrating a semiconductor device manufacturing method according to Embodiment 2 of the present invention. The method of removing the Al oxide formed on the first wire in the manufacturing method of Embodiment 2 is different from that in the manufacturing method of Embodiment 1.

First, referring to FIG. 4A, a lithography step is performed to form a resist. Then, an etching process is performed using the resist as a mask so as to form a first wire trench 2 in a first interlayer dielectric film 1, the first interlayer dielectric film 1 being formed of a low dielectric constant material on a substrate (not shown). Next, as a preparatory process, an annealing process is performed on the substrate (semiconductor device) for 60 seconds in a hydrogen atmosphere at a temperature of 280° C. so as to reduce an oxide formed on a surface of the semiconductor device. Then, as a barrier metal film 3, a tantalum nitride film having a thickness of 5 nm and a tantalum film having a thickness of 10 nm are formed by, for example, sputtering. In this case, the barrier metal film 3 is a metal film preventing the copper, which is a wiring material, from diffusing into the first interlayer dielectric film 1 provided around the wiring material.

Subsequently, referring to FIG. 4B, a seed film 4 having a thickness of 40 nm is formed on the barrier metal film 3 by, for example, sputtering. In this case, copper containing 1% Al by weight is used as a material for the seed film 4. A purpose of adding metal to copper is to improve, for example, electromigration resistance and stress migration resistance, and thus to improve the reliability of the semiconductor device.

Next, a copper film 5 is formed on the seed film 4 by using a plating method to fill the first wire trench 2. Then, the copper film 5, the seed film 4, and the barrier metal film 3 are polished by CMP such that the barrier metal film 3, the seed film 4, and the copper film 5 remain only in the first wire trench 2 as shown in FIG. 4C. In this way, a first wire is formed. In the step of forming the first wire, Al included in the seed film 4 diffuses into the copper film 5. Moreover, Al included in the seed film 4 reacts with atmospheric oxygen, which results in an Al oxide film 13 including a thin Al₂O₃ film formed on upper end surfaces of the seed film 4.

Next, referring to FIG. 4D, a liner film 6 having a thickness of about 60 nm is formed on the first wire and on the first interlayer dielectric film 1 by, for example, CVD. In this case, the liner film 6 prevents the copper included in the first wire from diffusing into a second interlayer dielectric film which is to be formed in a later step. The liner film 6 is formed by, for example, a silicon-carbon film or silicon nitride film having the relative dielectric constant higher than that of a material for the interlayer dielectric film. Note that, heating during the formation of the liner film 6 causes Al included in the seed film 4 to diffuse into the vicinity of an upper surface of the copper film 5. Therefore, a thin Al oxide film 13 is also formed on the upper surface of the copper film 5.

Next, referring to FIG. 4E, a second interlayer dielectric film 7 of a low dielectric constant material is formed on the liner film 6 by, for example, CVD. Heating during the formation of the second interlayer dielectric film 7 also causes Al to diffuse into the copper film 5.

Subsequently, referring to FIG. 4F, lithography and etching steps are performed repeatedly in order to form a via hole 8 reaching the copper film 5 and a second wire trench 9 to which the via hole 8 is open in the second interlayer dielectric film 7. Moreover, an opening 18 is formed in the liner film 6. In this step, the upper surface of the copper film 5 is exposed, so that the thickness of the Al oxide film 13 formed on the upper surface of the copper film 5 increases. In this step, a larger amount of Al oxide is formed than in other steps. Then, as a preparatory process, the semiconductor device is processed for 60 seconds in a hydrogen plasma atmosphere at a temperature of 280° C. so as to remove an oxide and the Al oxide 13 formed on a surface of the semiconductor device. As a result, the Al oxide film 13 formed on the upper surface of the copper film 5 and on the upper end surfaces of the seed film 4 remains only in a region in which the Al oxide film 13 is in contact with the liner film 6. That is, a part of the Al oxide film 13 which is not exposed remains.

Next, referring to FIG. 4G, a tantalum nitride film having a thickness of 5 nm and a tantalum film having a thickness of 10 nm are sequentially formed as a barrier metal film 10. Note that, the preparatory process using the hydrogen plasma and the step of forming the barrier metal film 10 are sequentially performed in vacuum.

Subsequently, referring to FIG. 4H, a seed film 11 having a thickness of about 40 nm is formed on the barrier metal film 10 by, for example, sputtering. In this case, as a material for the seed film 11, copper containing 1% Al by weight is used. A purpose of adding metal to copper is to improve, for example, electromigration resistance and stress migration resistance, and thus to improve the reliability of the semiconductor device.

Next, referring to FIG. 4I, a copper film is formed on the seed film 11 by using a plating method such that the copper film fills the second wire trench 9, the via hole 8, and the opening 18. Then, CMP is performed to polish the barrier metal film 10, the seed film 11, and the copper film in order to expose an upper surface of the second interlayer dielectric film 7. As a result, a second line including the barrier metal film 10, the seed film 11, and the copper film 12 are formed, wherein the barrier metal film 10, the seed film 11, and the copper film 12 are provided on inner surfaces of the second wire trench 9, the via hole 8, and the opening 18. In this way, an embedded wire according to Embodiment 2 is formed.

As shown in FIG. 41, the semiconductor device manufactured according to the method of Embodiment 2 includes: the first interlayer dielectric film 1 on the substrate formed of, for example, silicon, the first interlayer dielectric film 1 including the low dielectric constant material which has the first wire trench 2; the barrier metal film 3 on an inner surface of the first wire trench 2, the barrier metal film 3 being formed of, for example, the tantalum nitride film and the tantalum film; the seed film 4 on the barrier metal film 3, the seed film 4 being formed of copper containing, for example, 1% Al by weight; the copper film 5 on the seed film 4, the copper film 5 being provided in the first wire trench 2; the liner film 6 on the first interlayer dielectric film 1, the liner film 6 being formed of a dielectric film which has the opening 18 formed in a region over the copper film 5 seen in a plan view; and the Al oxide film 13 formed between the upper end surfaces of the seed film 4 and copper film 5 and the liner film 6. The semiconductor device according to Embodiment 2 further includes: the second interlayer dielectric film 7 including the low dielectric constant material in which the via hole 8 and the second wire trench 9 are formed, one end of the via hole 8 being open to the opening 18 of the liner film 6 and the other end of the via hole 8 being open to the second wire trench 9; the barrier metal film 10 on the inner surfaces of the second wire trench 9, the via hole 8, and the opening 18, the barrier metal film 10 being formed of, for example, the tantalum nitride film and the tantalum film; the seed film 11 on the barrier metal film 10, the seed film 11 including copper which contains, for example, 1% Al by weight; and the copper film 12 on the seed film 11, the copper film 12 being provided in the second wire trench 9, the via hole 8, and the opening 18. The width of the second wire trench is, for example, 0.1 μM and the depth is, for example, 0.15 μm.

Next, the reason will be explained why in the manufacturing method of Embodiment 2, the process using the hydrogen plasma is performed before the barrier metal film of the second wire is formed.

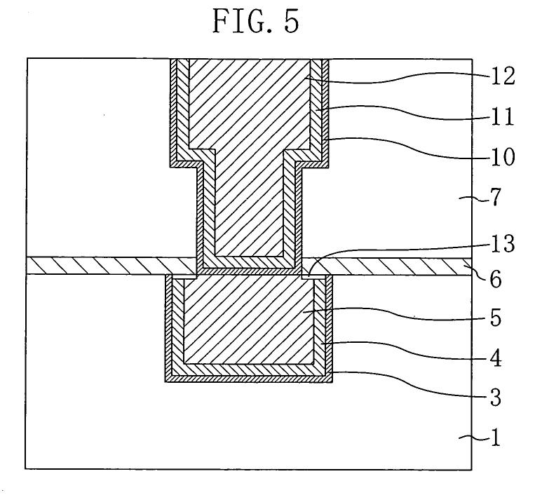

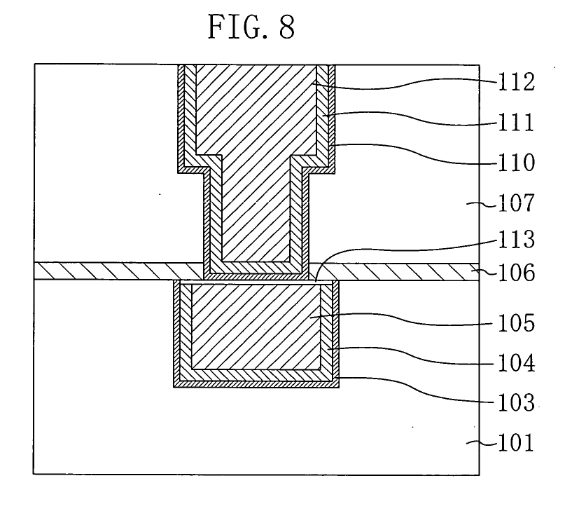

FIG. 5 is a cross section of the device of Embodiment 2, with which the characteristics of the semiconductor device manufacturing method of Embodiment 2 are described. As explained with reference to FIG. 8, it can be considered that in the conventional semiconductor device manufacturing method, the increased resistance value between the wire and the plug is attributable to the Al oxide film 13 formed on the upper surface of the copper film. Therefore, it is necessary to remove the Al oxide film 13.

TABLE 1

| | Hydrogen Anneal | Hydrogen Plasma |
|---|---|---|
| Cu Oxide | 1 | 10 |
| (Cu—O) | | |
| Al Oxide | 0.15 | 1.1 |
| (Al—O) | | |

Arbitrary Unit

Table 1 comparatively shows the removal rate of metal oxides. In the conventional manufacturing method, the hydrogen annealing process is performed as a preparatory process before the barrier metal film 10 (see FIG. 4G) of the second wire is formed. In the hydrogen annealing process, the removal rate of the Cu oxide is appropriate, but the removal rate of the Al oxide is only about one sixth that of the Cu oxide. Compared to this, in the manufacturing method of Embodiment 2, the hydrogen plasma process is performed. It can be thought that the hydrogen plasma process can reduce and remove the Al oxide film 13, because the hydrogen plasma process has the strong capability in reducing oxides. Indeed, it is verified that in the semiconductor device of Embodiment 2, the resistance value between the wire and the plug does not increase, and that the semiconductor device of Embodiment 2 has a preferred resistance value distribution, that is, all of the resistance values are 2×10¹⁷ Ω or lower.

The semiconductor device according to Embodiment 2 is described with reference to the example of using copper in which 1% Al is added as materials for the seed films 4 and 11. However, regardless of the amount of Al added, removing the Al oxide achieves the lowered electric resistance between the wire and the plug. Moreover, metal to be added to materials forming the seed films 4 and 11 is not limited to Al. Any metal having binding energy with oxygen higher than copper may be used. For example, Mg, Zn, Fe, Sn, or Ti may be added to materials forming the seed films 4 and 11.

Embodiment 2 is explained with reference to the example where the re-sputtering is not performed after the barrier metal film of the second wire is formed. However, the hydrogen plasma process before the formation of the barrier metal film may be combined with the re-sputtering process for removing the Al oxide film 13 formed on the copper film of the first wire described in Embodiment 1. The re-sputtering process thickens the barrier metal film on the inner surface of the via hole 8, which can also improve electromigration resistance and stress migration resistance.

The manufacturing method in Embodiment 1 is effective also in a case where the seed film 11 of the second wire consists of copper.

In the description above, an example where two embedded wires are formed has been explained. However, repeating the similar wire formation step can form wires in multiple layers.

The embedded wire structure of the present invention described above is applicable to, for example, general semiconductor integrated circuits.

What is claimed is:

1. A semiconductor device comprising:
a first interlayer dielectric film on a substrate,
a first wire in the first interlayer dielectric film, the first wire including a first wiring material film which contains at least one element of metal,
a second interlayer dielectric film on the first interlayer dielectric film and the first wire, the second interlayer dielectric film having a trench in which the first wiring material film is exposed,
an oxide film of the metal between an upper end surface of the first wiring material film and the second interlayer dielectric film, and
a second wire including a barrier metal film and a second wiring material film in the trench.

2. A semiconductor device of claim 1, wherein the trench is formed by a via hole reaching the first wiring material film and a wire trench reaching the via hole.

3. A semiconductor device of claim 1, wherein
an upper part of the first wiring material film has a concavity,
the concavity is covered by the barrier metal film, and
the second wiring material film is also provided in the concavity.

4. A semiconductor device of claim 1, wherein an upper surface of the first wiring material film is flat.

5. A semiconductor device of claim 1, further comprising:
a liner dielectric film between the first interlayer dielectric film and the second interlayer dielectric film, the liner dielectric film having an opening in a region on the first wiring material film, wherein
the oxide film of the metal is formed between an upper surface of the first wire including the first wiring material film and a lower surface of the liner dielectric film,
the opening is covered by the barrier metal film, and
the second wiring material film is also provided in the opening.

6. A semiconductor device of claim 1, wherein
the first wiring material film and the second wiring material film are of copper, and
the metal has binding energy with oxygen higher than the first wiring material film and the second wiring material film.

7. A semiconductor device of claim 6, wherein the metal contains at least one element selected from the group consisting of Al, Mg, Zn, Fe, Sn, and Ti.

8. A semiconductor device manufacturing method comprising the steps of:
(a) forming a first wiring material film in a first interlayer dielectric film formed on a substrate,
(b) forming a second interlayer dielectric film on the first wiring material film and on the first interlayer dielectric film,
(c) forming a trench in the second interlayer dielectric film to expose the first wiring material film,
(d) forming a barrier metal film in the trench,
(e) forming a concavity in an upper part of the first wiring material film by removing a part of the barrier metal film over the first wiring material film and a part of the first wiring material, and
(f) forming a second wiring material film to fill the trench and the concavity, wherein
the first wiring material film contains at least one element of metal,
an oxide film of the metal is formed on an upper surface of the first wiring material film in steps (a) and (c), and
step (e) includes removing an exposed part of the oxide film of the metal formed on the upper surface of the first wiring material film.

9. A semiconductor device of claim 8, wherein step (e) is performed by a re-sputtering process.

10. A semiconductor device manufacturing method comprising the steps of:
(a) forming a first wiring material film in a first interlayer dielectric film formed on a substrate,
(b) forming a second interlayer dielectric film on the first wiring material film and the first interlayer dielectric film,
(c) forming a trench in the second interlayer dielectric film to expose the first wiring material film,
(d) performing a hydrogen plasma process on the first wiring material film,
(e) after step (d), forming a barrier metal film in the trench, and
(f) after step (e), forming a second wiring material film to fill the trench, wherein
the first wiring material film contains at least one element of metal,
an oxide film of the metal is formed on an upper surface of the first wiring material film in steps (a) and (c), and
step (d) includes removing an exposed part of the oxide film of the metal formed on the upper surface of the first wiring material film.

11. A semiconductor device manufacturing method of claim 8, wherein step (c) includes the steps of:
(c1) forming a via hole reaching the first wiring material film, and
(c2) forming a wire trench reaching the via hole.

12. A semiconductor device manufacturing method of claim 8, further comprising the step of:
after step (a) and before step (b), forming a liner dielectric film on the first interlayer dielectric film, wherein
step (b) includes forming the second interlayer dielectric film on the liner dielectric film, and
step (c) includes forming an opening in a part of the liner dielectric film on the first wiring material film.

13. A semiconductor device manufacturing method of claim 8, wherein
the first wiring material film and the second wiring material film are of copper, and
the metal has binding energy with oxygen higher than the first wiring material film and the second wiring material film.

14. A semiconductor device manufacturing method of claim 13, wherein the metal contains at least one element selected from the group consisting of Al, Mg, Zn, Fe, Sn, and Ti.
